(19) United States
(12) Patent Application Publication
(10) Pub. No.: US 2014/0203883 A1
(43) Pub. Date: Jul. 24, 2014

(54) RESONATOR, OSCILLATOR, AND METHOD FOR FABRICATING OSCILLATOR

(71) Applicant: Nihon Dempa Kogyo Co., Ltd., Tokyo (JP)

(72) Inventors: TAKAHIRO OHTSUKA, SAITAMA (JP); MAKIKO NAKAMURA, SAITAMA (JP); NORITOSHI KIMURA, SAITAMA (JP)

(73) Assignee: Nihon Dempa Kogyo Co., Ltd., Tokyo (JP)

(21) Appl. No.: 14/161,711

(22) Filed: Jan. 23, 2014

(30) Foreign Application Priority Data
Jan. 23, 2013 (JP) 2013-010273

(51) Int. Cl. H02N 1/00; B81C 1/00; H03B 1/00

(52) U.S. Cl. CPC H02N 1/00; H03B 1/00; B81C 1/00523
USPC 331/156; 310/309; 216/36

(57) ABSTRACT

A resonator includes a ring-shaped or disk-shaped resonator main body, a supporting joist, and a securing portion. The supporting joist extends from the resonator main body to support the resonator main body. The securing portion is formed at a distal end of the supporting joist and the securing portion is secured to a base material. The securing portion includes a first rod-shaped portion and a second rod-shaped portion. The first rod-shaped portion is formed in a first direction. The second rod-shaped portion is formed in a second direction different from the first direction.

### CROSS REFERENCE TO RELATED APPLICATIONS

This application claims the priority benefit of Japan application serial no. 2013-010273, filed on Jan. 23, 2013. The entirety of the above-mentioned patent application is hereby incorporated by reference herein and made a part of this specification.

### FIELD

This disclosure relates to a resonator, an oscillator, and a method for fabricating the oscillator.

### DESCRIPTION OF THE RELATED ART

Nowadays, study and development have been made for fabricating microminiature and ultrahigh-performance electronic components using micro electro mechanical system (MEMS) technology. One of known electronic components fabricated using the MEMS technology is a MEMS resonator (or a MEMS resonator device hereinafter referred to simply as a resonator) formed on a substrate of a semiconductor such as silicon (for example, see Japanese Unexamined Patent Application Publication No. 2006-329931 (hereinafter referred to as Patent Literature 1)). A resonator disclosed in Patent Literature 1 includes a disk-shaped resonator main body, a supporting joist, which extends from the resonator main body, and a circular securing portion, which is formed at a distal end of the supporting joist to be secured to a base material.

This resonator is formed by forming a sacrificial layer on the base material, forming a layer that constitutes the resonator main body and similar portion on the sacrificial layer, and then removing the sacrificial layer after forming a pattern of the resonator main body and similar portion. In this resonator, the securing portion secured to the base material separates the resonator main body and the supporting joist from the base material. When the securing portion is secured to the base material, typically, an opening portion is formed in the sacrificial layer via a through-hole (an anchor hole) of the securing portion, and the through-hole (the securing portion) and the base material are bonded with silicon via this opening portion.

However, while in a fabrication process of the resonator disclosed in Patent Literature 1 the opening portion is formed in the sacrificial layer via the through-hole, only the top surface side of the base material is open. Therefore, an exposure process, a cleaning process, and similar process may be insufficient. As a result, foreign matter, for example, adhesion of residue of the sacrificial layer, an etching solution, or a dissolved matter, and formed watermarks due to cleaning remain on the inner wall and the base material surface of the through-hole. Bonding the through-hole and the base material in this state with silicon or similar material does not only reduces the bonding strength, but also increases the equivalent motional resistance due to the presence of the high-resistance foreign matter layer. This leads to a problem that this causes degradation of characteristics.

A need thus exists for a resonator, an oscillator, and a method for fabricating the oscillator which are not susceptible to the drawback mentioned above.

### SUMMARY

According to this disclosure, a resonator includes a ring-shaped or disk-shaped resonator main body, a supporting joist, and a securing portion. The supporting joist extends from the resonator main body to support the resonator main body. The securing portion is formed at a distal end of the supporting joist. The securing portion is secured to the base material. The securing portion includes a first rod-shaped portion and a second rod-shaped portion. The first rod-shaped portion is formed in a first direction. The second rod-shaped portion is formed in a second direction different from the first direction.

### BRIEF DESCRIPTION OF THE DRAWINGS

The foregoing and additional features and characteristics of this disclosure will become more apparent from the following detailed description considered with reference to the accompanying drawings, wherein:

FIG. 1A and FIG. 1B illustrate a resonator according to a first embodiment, FIG. 1A is an perspective view of the overall resonator, and FIG. 1B is an enlarged perspective view of a region A of FIG. 1A;

FIG. 2A is a plan view illustrating a part of a resonator according to a second embodiment and FIG. 2B is a plan view illustrating a part of a resonator according to a third embodiment;

FIG. 3 is a plan view illustrating a part of a resonator according to a fourth embodiment;

FIG. 4A is a plan view illustrating a part of a resonator according to a fifth embodiment, and FIG. 4B is a plan view illustrating a part of a resonator according to a sixth embodiment;

FIG. 5 is a graph illustrating a relationship between a length (dimension) in the Y direction of a second rod-shaped portion and strain energy at a securing portion;

FIG. 6 is a perspective view illustrating an embodiment of an oscillator;

FIG. 7A is a sectional drawing taken along the line VIIA-VIIA of FIG. 6, and FIG. 7B is a sectional drawing taken along the line VIIB-VIIB of FIG. 7A;

FIG. 8A to FIG. 8D are sectional drawings illustrating a fabrication process of the oscillator;

FIG. 9E to FIG. 9G are sectional drawings illustrating a fabrication process of the oscillator;

FIG. 10H to FIG. 10J are sectional drawings illustrating a fabrication process of the oscillator; and

FIG. 11A to FIG. 11F are plan views illustrating securing portions of other embodiments.

### DETAILED DESCRIPTION

Embodiments of this disclosure will be described with reference to the accompanying drawings. In each drawing below, when the configuration of the resonator is described, an XYZ coordinate system is used to describe directions in the drawings for ease of notation. In the XYZ coordinate system, a planar surface parallel to a base material surface on which a resonator is formed is denoted as an XY plane. In this XY plane, a predetermined direction is denoted as an X direction, and a direction perpendicular to the X direction is denoted as a Y direction. A direction perpendicular to the XY plane (a thickness direction of the base material) is denoted as a Z direction. Each of the X direction, the Y direction, and the Z direction is described to have a positive direction in the direction of the arrow in the drawings and a negative direction in the reverse direction of the direction of the arrow. A direction around the Z-axis may be denoted as a θZ-axis direction. In order to describe the embodiment, the drawings are expressed by changing the scale as necessary. For example, the illustration is partially enlarged or emphasized.

### First Embodiment

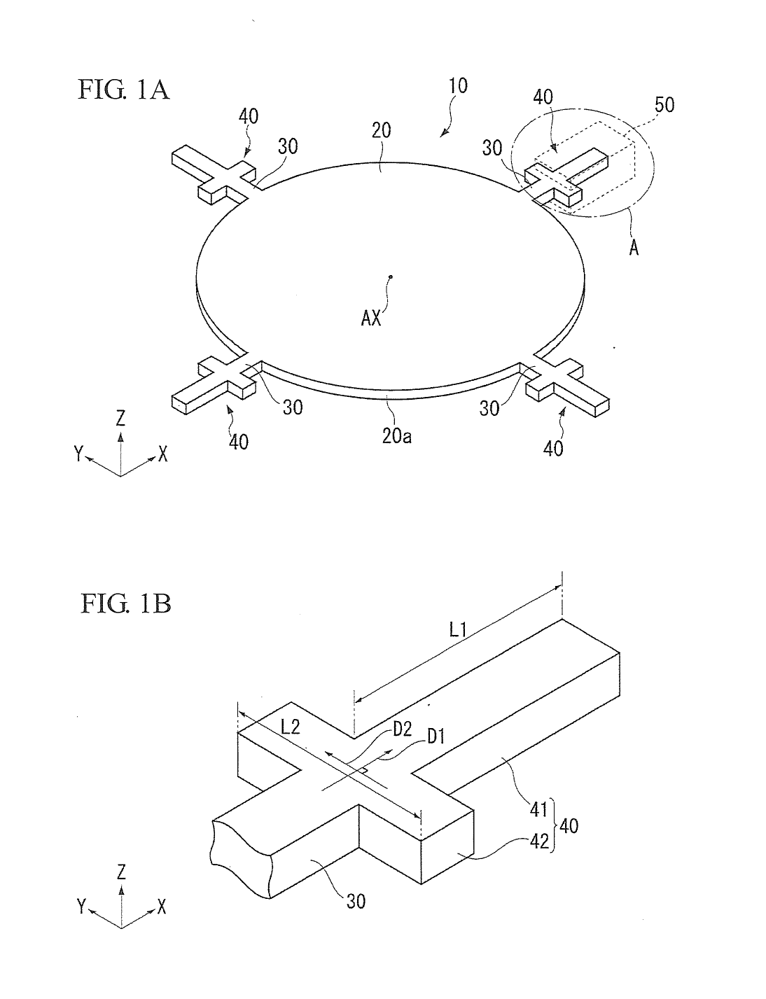

FIG. 1A illustrates a configuration of a resonator 10 according to a first embodiment. The resonator 10 is formed using the MEMS technology on a base material made of, for example, a single-crystal silicon, a polycrystalline silicon, a single crystal diamond, or a polycrystalline diamond. The resonator 10 includes a disk portion (resonator main body) 20, a plurality of supporting joists 30, and securing portions 40. The disk portion 20 is formed to be elastically deformable. The plurality of supporting joists 30 extends from an outer periphery 20a of the disk portion 20. The securing portions 40 are disposed at distal ends of the respective supporting joists 30.

The disk portion 20 is a vibrating body that resonates with vibration at a predetermined frequency. Means for transmitting vibration to the disk portion 20 is, for example, applying a predetermined voltage to electrodes arranged close to the outer periphery 20a of the disk portion 20. In this case, applying an alternating electrical signal to these electrodes changes an electrostatic force generated between the electrodes and the disk portion 20, with a predetermined period. This change in electrostatic force acts on the disk portion 20 so as to generate vibration on in the disk portion 20.

The disk portion 20 has, for example, a circular plate shape that is centered at a central axis AX parallel to the Z-axis. The disk portion 20 is arranged separately from the surface of the base material not to be in contact with the base material, in order to avoid vibration directly transmitted to the base material so as to ensure free vibrations. The disk portion 20 has a uniform thickness (a dimension in the Z direction) over the entire surface of the disk portion 20. The disk portion 20 includes a front surface (a surface on the +Z side) and a back surface (a surface on the −Z side) that are each formed as a flat planar surface and arranged parallel to the surface of the base material. Here, the back surface (the surface on the −Z side) of the disk portion 20 is spaced at a certain interval from the surface of the base material.

As illustrated in FIG. 1A, the disk portion 20 is not limited to have a circular plate shape. For example, any shape such as a multangular shape such as a quadrangular shape, a hexagonal shape, and an octagon, an elliptical shape, and an oval-like shape may be employed. The disk portion 20 also has a cross section (for example, the cross section in the XZ plane) in any shape such as a circular shape, an oval shape, a polygonal shape, and similar shape other than a rectangular shape.

The supporting joist 30 is formed to outwardly extend from the outer periphery 20a of the disk portion 20 in a radial direction (a radiation direction from a central axis AX) of the disk portion 20 and to be integrated with the disk portion 20. The supporting joist 30 supports the disk portion 20 from the outer periphery side. The supporting joists 30 are arranged at intervals of 90 degrees along the outer peripheral direction (the θZ direction) of the disk portion 20, and a total of four supporting joists 30 are disposed. The number of the supporting joists 30 is not limited to four, and may be any of one or plural. In the case where a plurality of the supporting joists 30 are formed, the supporting joists 30 are not limited to be formed at regular intervals and may be formed at different intervals. The supporting joist 30 has a thickness (a dimension in the Z direction) equal to the thickness of the disk portion 20. The four supporting joists 30 each have the same shape. This, however, should not be construed in a limiting sense. The supporting joists may have mutually different shapes. The supporting joist 30 is designed to have any length.

The securing portions 40 are each disposed at a distal end of the supporting joist 30 and each secured to the base material via a bonding portion 50 described later. FIG. 1B illustrates an enlarged region A illustrated in FIG. 1A. As illustrated in FIG. 1B, the securing portion 40 includes a first rod-shaped portion 41 and a second rod-shaped portion 42. The first rod-shaped portion 41 is formed to extend from the distal end portion of the supporting joist 30 in the extending direction of the supporting joist 30. The second rod-shaped portion 42 is framed in a direction perpendicular to the extending direction of the supporting joist 30 from the distal end portion of the supporting joist 30. The first rod-shaped portion 41 and the second rod-shaped portion 42 are held by the bonding portion 50 described later. In FIG. 1B, the extending direction of the supporting joist 30 will be described as the X direction. The first embodiment has a configuration where the first rod-shaped portion 41 protrudes from the side surface on the +X side of the second rod-shaped portion 42 in the +X direction.

The first rod-shaped portion 41 is formed to have a length L1 in the extending direction of the supporting joist 30 as a first direction D1 (the X direction, a radiation direction from the central axis AX). However, the first direction D1 is not limited to the extending direction of the supporting joist 30. For example, the first direction D1 may be a direction inclined by θ from the X direction in the XY plane. Designing the first direction D1 in the extending direction of the supporting joist 30 facilitates pattern formation during fabrication. The first rod-shaped portion 41 is formed in the rectangular shape similar to that of the supporting joist 30 when viewed from the X direction. The first rod-shaped portion 41 has respective dimensions in the width direction (the Y direction) and the thickness direction (the Z direction) that are the same as those of the supporting joist 30. However, the width and the thickness of the first rod-shaped portion 41 are not limited to be the same as those of the supporting joist 30. For example, the width may be larger than that of the supporting joist 30. The first rod-shaped portion 41 is formed to have a constant cross-sectional area (a cross-sectional area of a surface parallel to the YZ plane) along the longitudinal direction (the first direction D1). Here, the length L1 of the first rod-shaped portion 41 has any length.

The second rod-shaped portion 42 is formed to have a length L2 in a direction (the Y direction) perpendicular to the extending direction of the supporting joist 30 as a second direction D2. However, the second direction D2 is not limited to the direction perpendicular to the first direction D1, and may be any direction different from the first direction D1. The length L2 of the second rod-shaped portion 42 is equal to the length L1 or shorter than the length L1 of the first rod-shaped portion 41. The second rod-shaped portion 42 is formed in a rectangular shape similar to those of the supporting joist 30 and the first rod-shaped portion 41 when viewed from the Y direction. The second rod-shaped portion 42 has respective dimensions of the width direction (the X direction) and the thickness direction (the Z direction) that are the same as those of the supporting joist 30 and the first rod-shaped portion 41. However, the width and the thickness of the second rod-shaped portion 42 are not limited to be the same as those of the first rod-shaped portion 41 and portion. For example, the width may be larger than the first rod-shaped portion 41 and similar portion.

The second rod-shaped portion 42 is formed to have a constant cross-sectional area (a cross-sectional area of a surface parallel to XZ plane) along the longitudinal direction (the second direction D2). Furthermore, in the second rod-shaped portion 42, the length extending in the +Y direction from the side surface on the +Y side of the first rod-shaped portion 41 and the length extending in the −Y direction from the side surface on the −Y side of the first rod-shaped portion 41 are approximately the same. This, however, should not be construed in a limiting sense. For example, the length extending in the +Y direction may be longer than the length extending in the −Y direction. Here, the length L2 of the second rod-shaped portion 42 has any length. The second rod-shaped portion 42 is not limited to be formed in the distal end portion of the supporting joist 30 (a portion at the disk portion 20 side of the first rod-shaped portion 41). For example, the second rod-shaped portion 42 may be formed in the middle portion, the distal end portion, or similar portion of the first rod-shaped portion 41. The first rod-shaped portion 41 and the second rod-shaped portion 42 both have the thickness equal to the thickness of the disk portion 20.

As illustrated by a dotted line in FIG. 1A, the bonding portion 50 for bonding the securing portion 40 and the base material together is formed, for example, to cover the entire first rod-shaped portion 41 and to expose a part of the second rod-shaped portion 42 (the −X side and both sides in the Y direction). However, the bonding portion 50 is not limited to expose a part of the second rod-shaped portion 42. For example, the bonding portion 50 may cover both the first rod-shaped portion 41 and the second rod-shaped portion 42.

The resonator 10 constituted as described above holds the securing portion 40 on the base material and separates the disk portion 20 from the base material surface. Applying a predetermined AC Voltage to the disk portion 20 so as to resonate the disk portion 20 (resonator 10) allows taking out a signal at a predetermined frequency. The resonator 10 has a mode of vibration such as a contour vibration (a contour mode), a wine glass mode, and similar mode. The disk portion 20 deforms corresponding to each mode of vibration. This displaces the supporting joist 30. At this time, the first rod-shaped portion 41 and the second rod-shaped portion 42 allows the securing portion 40 to support the supporting joist 30 in a plurality of directions of the first direction D1 and the second direction D2. Thus, the securing portion 40 strongly supports the supporting joist 30 against displacement of the supporting joist 30.

With the first embodiment, the disk portion 20 is held by the securing portion 40 that includes the first rod-shaped portion 41 along the first direction D1 and the second rod-shaped portion 42 along the second direction D2, thus being strongly supported with respect to the base material. The bonded portion with the base material does not employ an anchor hole, but employs the first rod-shaped portion 41 and similar portion. Accordingly, when the base material and the securing portion 40 are bonded together via the bonding portion such as silicon, foreign matter is unlikely to remain in the exposure process, the cleaning process, or similar process. This reduces invasion of foreign matter into the interface between the bonding portion and the base material and into the interface between the bonding portion and the securing portion, so as to enhance the bonding strength between both the portions. This reliably and stably secures the disk portion 20 to the base material. Furthermore, foreign matter does not intervene at the interface between the bonding portion and the base material or similar interface. This reduces an increase in equivalent motional resistance and provides a highly-reliable resonator.

### Second Embodiment

Next, a second embodiment will be described. In the following description, like reference numerals designate corresponding or identical elements throughout the first embodiment, and therefore such elements will not be further elaborated or will be simplified here.

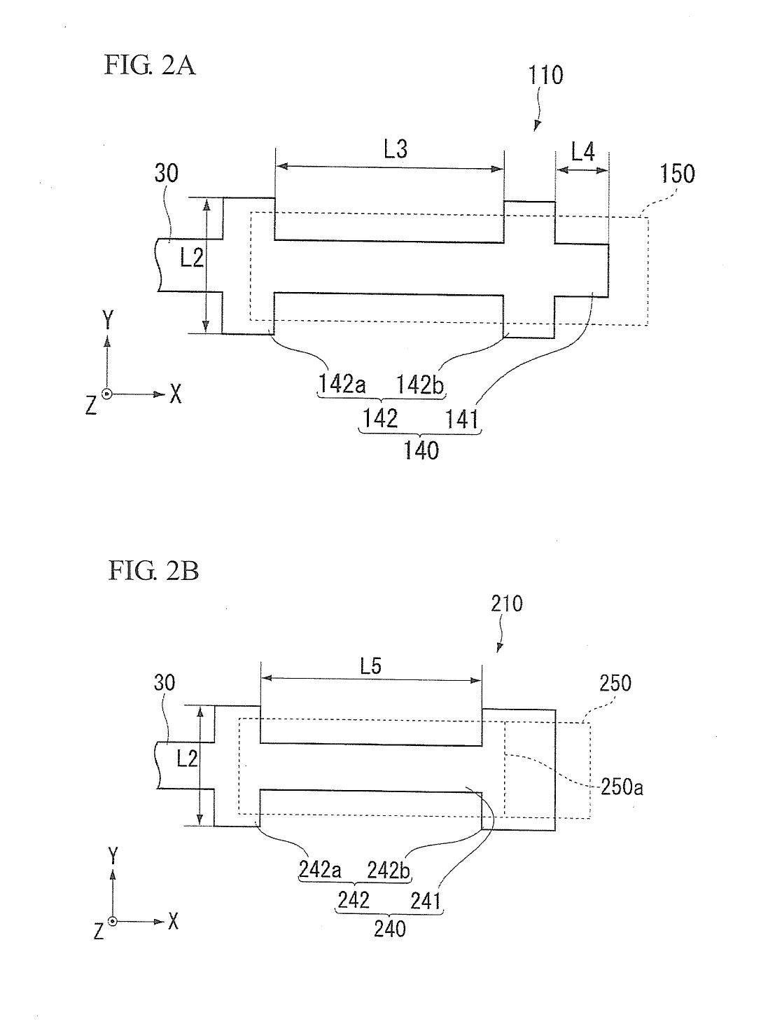

FIG. 2A illustrates a part of a resonator 110 according to the second embodiment. In FIG. 2A, the portion corresponding to the region A in FIG. 1A is illustrated and the disk portion is similar to the disk portion 20 in FIG. 1A. This resonator 110 differs from the first embodiment in that a securing portion 140 includes one first rod-shaped portion 141 and two second rod-shaped portions 142.

As illustrated in FIG. 2A, the second rod-shaped portion 142 includes a disk-side rod-shaped portion 142a and a distal end-side rod-shaped portion 142b. The disk-side rod-shaped portion 142a is formed at the distal end of the supporting joist 30. The distal end-side rod-shaped portion 142b is formed adjacent to a distal end of the first rod-shaped portion 141. The first rod-shaped portion 141 is constituted of a portion with a length L3 and a portion with a length L4. The portion with the length L3 extends from the disk-side rod-shaped portion 142a to the distal end-side rod-shaped portion 142b along the X direction (the first direction). The portion with the length L4 is disposed at a distal side of the distal end-side rod-shaped portion 142b along the X direction (the first direction). The disk-side rod-shaped portion 142a and the distal end-side rod-shaped portion 142b are each formed with the length L2 along the Y direction (the second direction), similarly to the second rod-shaped portion 42 of the first embodiment. The total length of the length L3 and the length L4 in the first rod-shaped portion 141 is larger than the length L2 of the disk-side rod-shaped portion 142a (or the distal end-side rod-shaped portion 142b).

The disk-side rod-shaped portion 142a and the distal end-side rod-shaped portion 142b employ the same shape. This, however, should not be construed in a limiting sense. For example, the distal end-side rod-shaped portion 142b may be formed longer than the disk-side rod-shaped portion 142a. The disk-side rod-shaped portion 142a and the distal end-side rod-shaped portion 142b are each orthogonal to the first rod-shaped portion 141. This, however, should not be construed in a limiting sense. For example, the disk-side rod-shaped portion 142a may be inclined with respect to the Y direction. The second rod-shaped portion 142 is not limited to include two of the disk-side rod-shaped portion 142a and the distal end-side rod-shaped portion 142b, and may include three or more portions.

The respective lengths L3 and L4 of the first rod-shaped portion 141 can be arbitrarily designed. Furthermore, the ratio of the length L3 and the length L4 (or a position where the distal end-side rod-shaped portion 142b is formed) can be arbitrarily designed. The length L3 portion and the length L4 portion are both formed along the X direction. This, however, should not be construed in a limiting sense. For example, the length L4 portion may be inclined with respect to the X direction.

As illustrated by a dotted line in FIG. 2A, a bonding portion 150 for bonding this securing portion 140 and the base material together is formed, for example, to cover the entire first rod-shaped portion 141 and to expose a part of the second rod-shaped portion 142 (the −X side and both sides in the Y direction of the disk-side rod-shaped portion 142a, and both sides in the Y direction of the distal end-side rod-shaped portion 142b). However, the bonding portion 150 is not limited to expose a part of the second rod-shaped portion 142. For example, the bonding portion 150 may cover both the first rod-shaped portion 141 and the second rod-shaped portion 142.

With the second embodiment, the disk portion is supported by the securing portion 140 that includes the first rod-shaped portion 141 and the second rod-shaped portion 142. This reliably and stably secures the disk portion to the base material similarly to the first embodiment. Furthermore, forming the plurality of the second rod-shaped portions 142 expands the bonded area with the bonding portion 150 and improves torsional rigidity. Additionally, the bonding portion 150 strongly restricts the movement of the securing portion 140 in the X direction. Thus, both the portions are more strongly bonded together so as to secure the disk portion more reliably.

### Third Embodiment

Next, a third embodiment will be described. In the following description, like reference numerals designate corresponding or identical elements throughout the first embodiment, and therefore such elements will not be further elaborated or will be simplified here.

FIG. 2B illustrates a part of a resonator 210 according to the third embodiment. In FIG. 2B, the portion corresponding to the region A in FIG. 1A is illustrated and the disk portion is similar to the disk portion 20 in FIG. 1A. This resonator 210 differs from the first embodiment in that a securing portion 240 includes one first rod-shaped portion 241 and two second rod-shaped portions 242.

As illustrated in FIG. 2B, the second rod-shaped portion 242 includes a disk-side rod-shaped portion 242a and a distal end-side rod-shaped portion 242b. The disk-side rod-shaped portion 242a is formed at the distal end of the supporting joist 30. The distal end-side rod-shaped portion 242b is formed at the distal end (the end portion at the +X side) of the first rod-shaped portion 241. The first rod-shaped portion 241 is formed with a length L5 from the disk-side rod-shaped portion 242a to the distal end-side rod-shaped portion 242b along the X direction (the first direction). The disk-side rod-shaped portion 242a and the distal end-side rod-shaped portion 242b are each formed with the length L2 along the Y direction (the second direction) similarly to the second rod-shaped portion 42 of the first embodiment. The length L5 of the first rod-shaped portion 241 is larger than the length L2 of the disk-side rod-shaped portion 242a (or the distal end-side rod-shaped portion 242b).

The distal end-side rod-shaped portion 242b is formed to be wider than the disk-side rod-shaped portion 242a in the width direction (the X direction). However, the respective widths of the disk-side rod-shaped portion 242a and the distal end-side rod-shaped portion 242b can be arbitrarily designed. In contrast to FIG. 2B, the width of the disk-side rod-shaped portion 242a may be wider than that of the distal end-side rod-shaped portion 242b. The disk-side rod-shaped portion 242a and the distal end-side rod-shaped portion 242b are not limited to have the same length L2. For example, the distal end-side rod-shaped portion 242b may be formed longer than the disk-side rod-shaped portion 242a. Furthermore, the disk-side rod-shaped portion 242a and the distal end-side rod-shaped portion 242b are each orthogonal to the first rod-shaped portion 241. This, however, should not be construed in a limiting sense. For example, the distal end-side rod-shaped portion 242b may be inclined with respect to the Y direction. Here, one or more other second rod-shaped portions may be formed between the disk-side rod-shaped portion 242a and the distal end-side rod-shaped portion 242b.

As illustrated by a dotted line in FIG. 2B, a bonding portion 250 for bonding this securing portion 240 and the base material together is formed, for example, to cover the entire first rod-shaped portion 241 and to expose a part of the second rod-shaped portion 242 (the −X side and both sides in the Y direction of the disk-side rod-shaped portion 242a, and both sides in the Y direction of the distal end-side rod-shaped portion 242b). Like a bonding portion 250a, the +X side of the distal end-side rod-shaped portion 242b may also be exposed. However, the bonding portion 250 is not limited to expose a part of the second rod-shaped portion 242. For example, the bonding portion 250 may cover both the first rod-shaped portion 241 and the second rod-shaped portion 242.

With the third embodiment, the disk portion is supported by the securing portion 240 that includes the first rod-shaped portion 241 and the second rod-shaped portion 242. Similarly to the first embodiment, this reliably and stably secures the disk portion to the base material. Furthermore, similarly to the second embodiment, forming the plurality of the second rod-shaped portions 242 secures the disk portion more reliably.

### Fourth Embodiment

Next, a fourth embodiment will be described. In the following description, like reference numerals designate corresponding or identical elements throughout the first embodiment, and therefore such elements will not be further elaborated or will be simplified here.

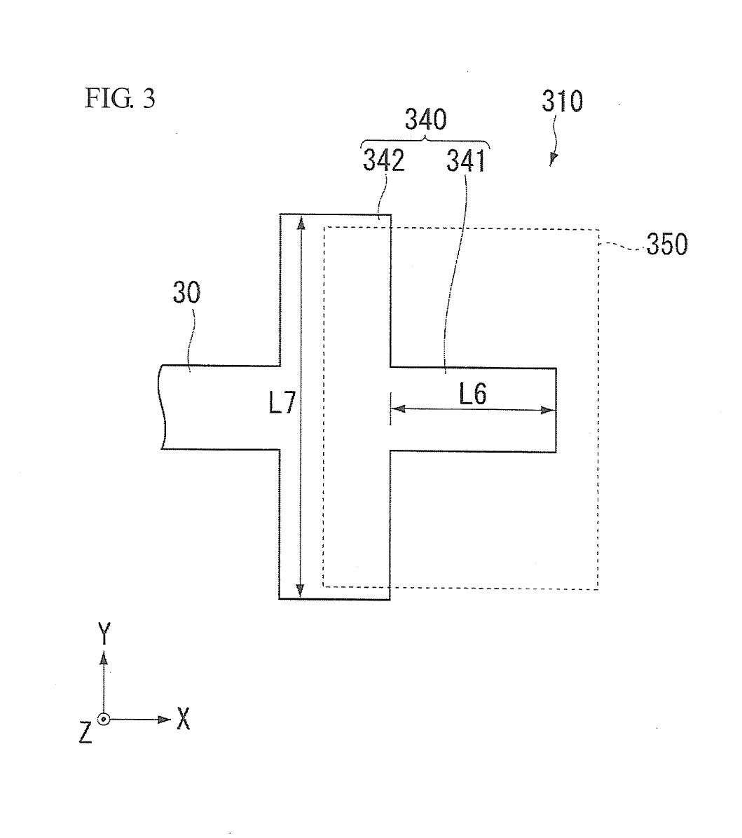

FIG. 3 illustrates a part of a resonator 310 according to the fourth embodiment. In FIG. 3, the portion corresponding to the region A in FIG. 1A is illustrated and the disk portion is similar to the disk portion 20 in FIG. 1A. This resonator 310 differs from the first embodiment in that a securing portion 340 includes a second rod-shaped portion 342 formed longer than a first rod-shaped portion 341.

As illustrated in FIG. 3, the first rod-shaped portion 341 is formed with a length L6 in the X direction (the first direction). The second rod-shaped portion 342 is formed with a length L7 in the Y direction (the second direction) at the distal end of the supporting joist 30. The length L6 of the first rod-shaped portion 341 is shorter than the length L7 of the second rod-shaped portion 342. However, the respective length L6 and length L7 can be arbitrarily designed insofar as the length L6 is shorter than the length L7. The first rod-shaped portion 341 and the second rod-shaped portion 342 are not limited to be perpendicular to each other. For example, the second rod-shaped portion 342 may be inclined with respect to the Y direction.

As illustrated by a dotted line in FIG. 3, a bonding portion 350 for bonding this securing portion 340 and the base material together is formed, for example, to cover the entire first rod-shaped portion 341 and to expose a part of the second rod-shaped portion 342 (the −X side and both sides of the Y direction). However, the bonding portion 350 is not limited to expose a part of the second rod-shaped portion 342. For example, the bonding portion 350 may cover both the first rod-shaped portion 341 and the second rod-shaped portion 342.

With the fourth embodiment, the disk portion is supported by the securing portion 340 that includes the first rod-shaped portion 341 and the second rod-shaped portion 342. Similarly to the first embodiment, this reliably and stably secures the disk portion to the base material. Furthermore, the short first rod-shaped portion 341 reduces the size of the region of the resonator 310 in the radial direction and provides a small oscillator. The long second rod-shaped portion 342 ensures a high torsional rigidity and secures the disk portion more reliably.

### Fifth Embodiment

Next, a fifth embodiment will be described. In the following description, like reference numerals designate corresponding or identical elements throughout the first embodiment, and therefore such elements will not be further elaborated or will be simplified here.

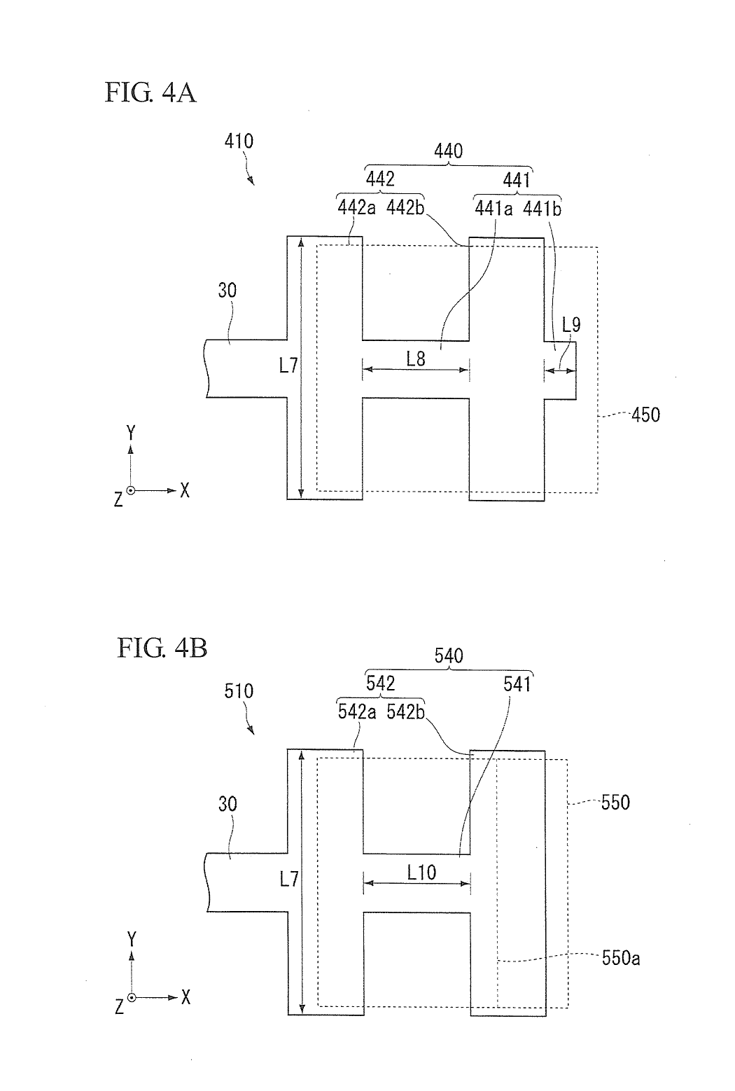

FIG. 4A illustrates a part of a resonator 410 according to the fifth embodiment. In FIG. 4A the portion corresponding to the region A in FIG. 1A is illustrated and the disk portion is similar to the disk portion 20 in FIG. 1A. This resonator 410 differs from the first embodiment in that a securing portion 440 includes one first rod-shaped portion 441 and two second rod-shaped portions 442.

As illustrated in FIG. 4A, the second rod-shaped portion 442 includes a disk-side of the second rod-shaped portion 442a and a distal end-side of the second rod-shaped portion 442b. The disk-side of the second rod-shaped portion 442a is formed at the distal end of the supporting joist 30. The distal end-side of the second rod-shaped portion 442b is formed adjacent to a distal end of the first rod-shaped portion 441. The first rod-shaped portion 441 is constituted of a portion with a length L8 and a portion with a length L9. A disk-side of the first rod-shaped portion 441a with the length L8 extends from the disk-side of the second rod-shaped portion 442a to the distal end-side of the second rod-shaped portion 442b along the X direction (the first direction). A distal end-side of the first rod-shaped portion 441b with the length L9 is disposed at a distal side of the distal end-side of the second rod-shaped portion 442b along the X direction (the first direction). The disk-side of the second rod-shaped portion 442a and the distal end-side of the second rod-shaped portion 442b are each formed with the length L7 along the Y direction (the second direction), similarly to the second rod-shaped portion 342 of the fourth embodiment. The total length of the length L8 and the length L9 in the first rod-shaped portion 441 is shorter than the length L7 of the disk-side of the second rod-shaped portion 442a (or the distal end-side of the second rod-shaped portion 442b).

The disk-side of the second rod-shaped portion 442a and the distal end-side rod-shaped of the second portion 442b have the same shape. This, however, should not be construed in a limiting sense. For example, the distal end-side of the second rod-shaped portion 442b may be formed longer than the disk-side of the second rod-shaped portion 442a. The disk-side of the second rod-shaped portion 442a and the distal end-side of the second rod-shaped portion 442b are each orthogonal to the first rod-shaped portion 441. This, however, should not be construed in a limiting sense. For example, the disk-side of the second rod-shaped portion 442a may be inclined with respect to the Y direction. The second rod-shaped portion 442 is not limited to include two of the disk-side of the second rod-shaped portion 442a and the distal end-side of the second rod-shaped portion 442b, and may include three or more portions.

The respective lengths L8 and L9 of the first rod-shaped portion 441 can be arbitrarily designed. Furthermore, the ratio of the length L8 and the length L9 (or the position where the distal end-side of the second rod-shaped portion 442b is formed) can be arbitrarily designed. However, the total length of the length L8 and the length L9 is designed shorter than the length L7. Both the length L8 portion and the length L9 portion are formed along the X direction. This, however, should not be construed in a limiting sense. For example, the length L9 portion may be inclined with respect to the X direction.

As illustrated by a dotted line in FIG. 4A, a bonding portion 450 for bonding this securing portion 440 and the base material together is formed, for example, to cover the entire first rod-shaped portion 441 and to expose a part of the second rod-shaped portion 442 (the −X side and both sides in the Y direction of the disk-side of the second rod-shaped portion 442a, and both sides in the Y direction of the distal end-side of the second rod-shaped portion 442b). However, the bonding portion 450 is not limited to expose a part of the second rod-shaped portion 442. For example, the bonding portion 450 may cover both the first rod-shaped portion 441 and the second rod-shaped portion 442.

With the fifth embodiment, the disk portion is supported by the securing portion 440 that includes the first rod-shaped portion 441 and the second rod-shaped portion 442. This reliably and stably secures the disk portion to the base material similarly to the first embodiment. Furthermore, the short first rod-shaped portion 441 reduces the size of the region of the resonator 410 in the radial direction and provides a small oscillator. Forming the plurality of the long second rod-shaped portions 442 expands the bonded area with the bonding portion 450 and improves torsional rigidity, thus securing the disk portion more reliably.

### Sixth Embodiment

Next, a sixth embodiment will be described. In the following description, like reference numerals designate corresponding or identical elements throughout the first embodiment, and therefore such elements will not be further elaborated or will be simplified here.

FIG. 4B illustrates a part of a resonator 510 according to the sixth embodiment. In FIG. 4B, the portion corresponding to the region A in FIG. 1A is illustrated and the disk portion is similar to the disk portion 20 in FIG. 1A. This resonator 510 differs from the first embodiment in that a securing portion 540 includes one first rod-shaped portion 541 and two second rod-shaped portions 542.

As illustrated in FIG. 4B, the second rod-shaped portion 542 includes a disk-side rod-shaped portion 542a and a distal end-side rod-shaped portion 542b. The disk-side rod-shaped portion 542a is formed at the distal end of the supporting joist 30. The distal end-side rod-shaped portion 542b is formed at a distal end (an end portion at the +X side) of the first rod-shaped portion 541. The first rod-shaped portion 541 is formed with a length L10 from the disk-side rod-shaped portion 542a to the distal end-side rod-shaped portion 542b along the X direction (the first direction). The disk-side rod-shaped portion 542a and the distal end-side rod-shaped portion 542b are each formed with a length L7 along the Y direction (the second direction) similarly to the second rod-shaped portion 342 of the fourth embodiment. The length L10 of the first rod-shaped portion 541 is shorter than the length L7 of the disk-side rod-shaped portion 542a (or the distal end-side rod-shaped portion 542b).

The disk-side rod-shaped portion 542a and the distal end-side rod-shaped portion 542b are not limited to have the same shape. For example, the length of the distal end-side rod-shaped portion 542b (the length along the Y direction) may be longer than that of the disk-side rod-shaped portion 542a. Alternatively, the width of the distal end-side rod-shaped portion 542b (the width along the X direction) may be wider than that of the disk-side rod-shaped portion 542a. Furthermore, the disk-side rod-shaped portion 542a and the distal end-side rod-shaped portion 542b are each orthogonal to the first rod-shaped portion 541. This, however, should not be construed in a limiting sense. For example, the distal end-side rod-shaped portion 542b may be inclined with respect to the Y direction. One or more other second rod-shaped portions may be formed between the disk-side rod-shaped portion 542a and the distal end-side rod-shaped portion 542b.

As illustrated by a dotted line in FIG. 2B, a bonding portion 550 for bonding this securing portion 540 and the base material together is formed, for example, to cover the entire first rod-shaped portion 541 and to expose a part of the second rod-shaped portion 542 (the −X side and both sides in the Y direction of the disk-side rod-shaped portion 542a, and both sides in the Y direction of the distal end-side rod-shaped portion 542b). Like a bonding portion 550a, the +X side of the distal end-side rod-shaped portion 542b may be exposed. However, the bonding portion 550 is not limited to expose a part of the second rod-shaped portion 542. For example, the bonding portion 550 may cover both the first rod-shaped portion 541 and the second rod-shaped portion 542.

With the sixth embodiment, the disk portion is supported by the securing portion 540 that includes the first rod-shaped portion 541 and the second rod-shaped portion 542. This reliably and stably secures the disk portion to the base material similarly to the first embodiment. Furthermore, the short first rod-shaped portion 541 reduces the size of the region of the resonator 510 in the radial direction and provides a small oscillator. Forming the plurality of the long second rod-shaped portion 542 expands the bonded area with the bonding portion 550 and improves the torsional rigidity, thus securing the disk portion more reliably.

Relationship Between this Embodiment and Strain Energy

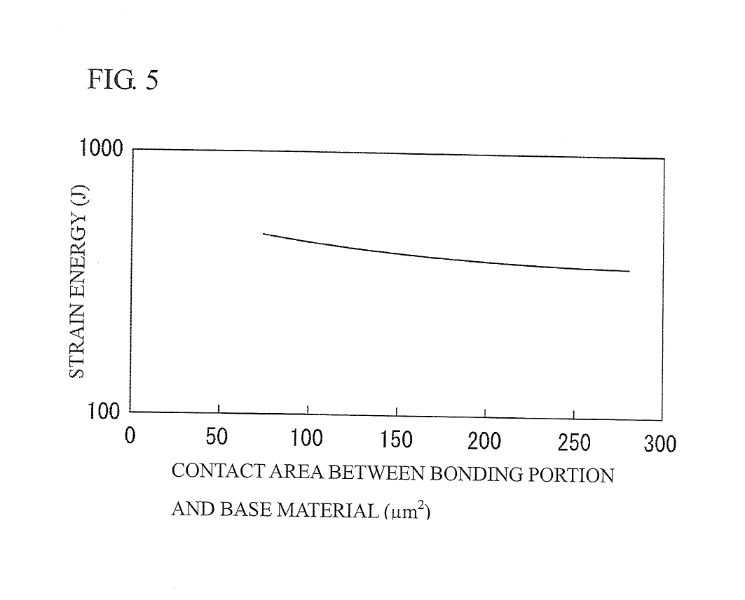

FIG. 5 is a graph illustrating a change in strain energy with respect to a change in contact area between the bonding portion 50 and the base material in the case where the length in the Y direction is changed while the length in the X direction is designed to have a fixed value in the securing portion 40 of the first embodiment. As illustrated in FIG. 5, the enlarged length in the Y direction increased the contact area. This shows a tendency that the strain energy (that is, anchor loss) decreased while an inflection point was not observed. It was confirmed that the strain energy gradually decreases with increasing contact area.

### Oscillator

### Configuration of Oscillator

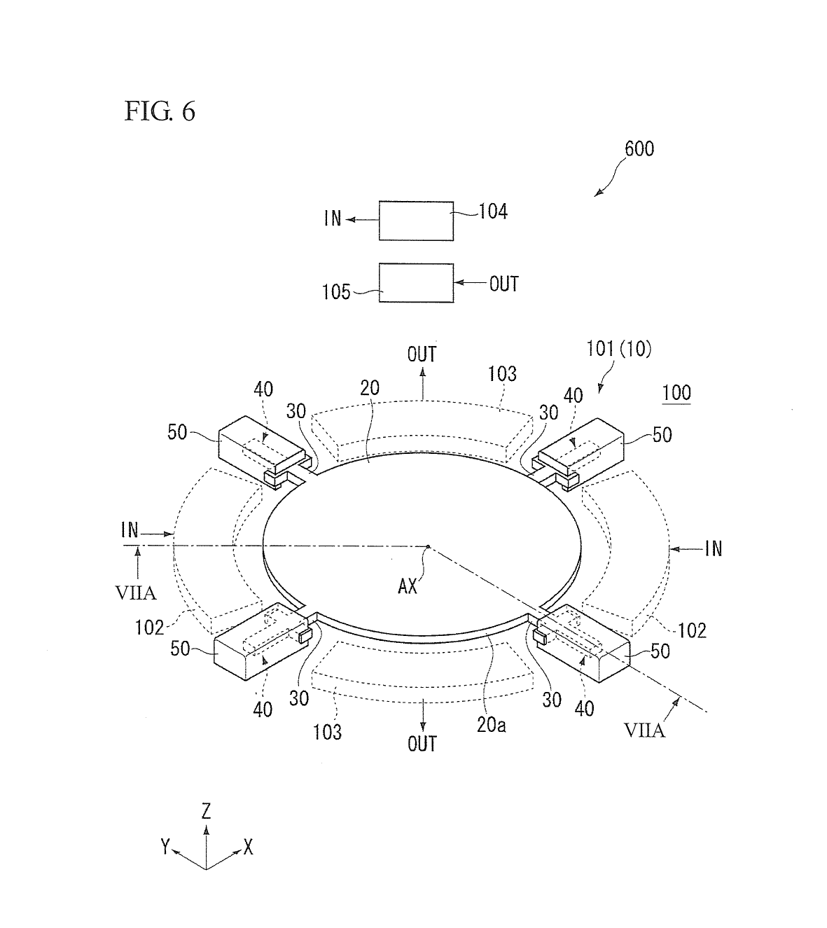

Next, an embodiment of the oscillator will be described. In the following description, like reference numerals designate corresponding or identical elements throughout the first embodiment, and therefore such elements will not be further elaborated or will be simplified here. FIG. 6 illustrates the embodiment of the oscillator. As illustrated in FIG. 6, an oscillator 600 includes a base material 100 and a resonator 101. The base material 100 is made of, for example, a single-crystal silicon, a polycrystalline silicon, a single crystal diamond, or a polycrystalline diamond. The resonator 101 is formed on a smooth surface of the base material 100 using a MEMS technology, and includes a disk-shaped vibrating body. The resonator 101 can employ the resonators 10, 110, 210, 310, 410, and 510 disclosed in the first embodiment to the sixth embodiment above. In this embodiment, the configuration using the resonator 10 described in the first embodiment will be described as an example.

On the base material 100, a plurality of input electrodes 102, a plurality of output electrodes 103, a driving circuit 104, and a detection circuit 105. The plurality of input electrodes 102 and the plurality of output electrodes 103 are alternately arranged along the outer periphery 20a of the disk portion 20 in the resonator 101. The driving circuit 104 applies AC Voltages to each of the input electrodes 102. The detection circuit 105 detects a capacitance between the output electrodes 103 and the disk portion 20.

The input electrodes 102 are arranged in two opposing positions while sandwiching the disk portion 20 in the radial direction. These input electrodes 102 are arranged at predetermined intervals from the disk portion 20 so as to have an inner peripheral side facing the outer periphery 20a of the disk portion 20. The input electrodes 102 are arranged at intervals of 180 degrees in the θZ direction. The output electrodes 103 are, similarly to the input electrodes 102, arranged in two positions facing each other while sandwiching the disk portion 20 in the radial direction. These output electrodes 103 are arranged at predetermined intervals between the output electrodes 103 and the disk portion 20 so as to have an inner peripheral side facing the outer periphery 20a of the disk portion 20. The output electrodes 103 are arranged at intervals of 180 degrees in the θZ direction in positions displaced from the input electrodes 102 by 90 degrees in the θZ direction. Here, the numbers, the shapes, and the locations of the input electrodes 102 and the output electrodes 103 can be arbitrarily designed.

The driving circuit 104 and the detection circuit 105 are disposed on the base material 100, and connect to the respective input electrodes 102 and output electrodes 103 via wiring or similar portion (not illustrated) also formed on the base material 100. Here, a controller for controlling operations of the driving circuit 104 and the detection circuit 105 is disposed on the base material 100 or outside of the base material 100.

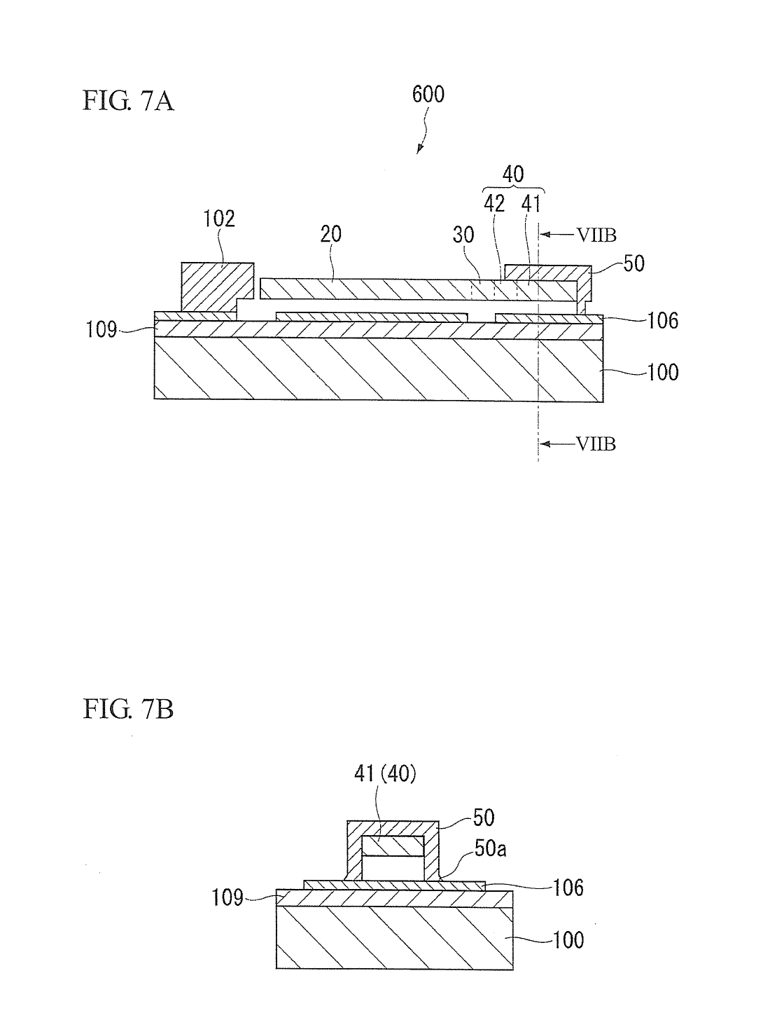

On the surface of the base material 100, as illustrated in FIG. 7A and FIG. 7B, a first insulating layer 109 is formed. On the surface of the first insulating layer 109, a wiring layer 106 is formed. The input electrodes 102 and the output electrodes 103 connect to the driving circuit 104 and the detection circuit 105 via this wiring layer 106.

The disk portion 20 is arranged with a gap from the surface of the base material 100 (the first insulating layer 109) and the wiring layer 106. The securing portion 40 includes a top surface, a distal end surface, and a side surface that are bonded to the bonding portion 50. This bonding portion 50 is bonded to the wiring layer 106 on the base material 100 so as to hold the base material 100. As illustrated in FIG. 7B, in the bonding portion 50, a bonding end portion 50a bonded to the wiring layer 106 has a shape expanding toward the wiring layer 106 side. This increases the bonding strength between the bonding portion 50 and the wiring layer 106.

Next, a description will be given of operation of the oscillator 600 constituted as described above. Firstly, the driving circuit 104 applies an alternating electrical signal to the input electrodes 102. This changes capacitance with a predetermined period in association with the change in electric potential between the input electrodes 102 and the disk portion 20. This change in capacitance changes an electrostatic force acting between the input electrodes 102 and the disk portion 20 with a predetermined period, thus vibrating the disk portion 20. The resonance of the resonator 10 due to the vibration of the disk portion 20 considerably displaces the disk portion 20 in the radial direction. Here, the mode of vibration may be any of a contour vibration (a contour mode) and a wine glass mode. The displacement of the disk portion 20 in the radial direction changes the capacitance between the disk portion 20 and the output electrodes 103. Detecting this change in capacitance by the detection circuit 105 allows taking out a signal at a predetermined frequency.

Instead of the description above, the driving circuit 104 may apply an alternating electrical signal to the output electrodes 103 and the detection circuit 105 may detect change in capacitance from the input electrodes 102. Even in this case, a similar result can be obtained.

Thus, with the oscillator 600, the disk portion 20 is held by the securing portion 40 that includes the first rod-shaped portion 41 and the second rod-shaped portion 42. Accordingly, the disk portion 20 is strongly supported on the base material 100. The bonded portion with the base material 100 does not employ an anchor hole, but employs the first rod-shaped portion 41 and similar portion. Therefore, when the base material 100 and the securing portion 40 are bonded together via the bonding portion 50, foreign matter is unlikely to remain in the exposure process, the cleaning process, or similar process. This reduces invasion of foreign matter into the interface between the bonding portion 50 and the base material 100 and into the interface between the bonding portion 50 and the securing portion 40, so as to enhance the bonding strength between both the portions. This reliably and stably secures the disk portion 20 to the base material 100. Furthermore, foreign matter does not intervene at the interface between the bonding portion 50 and the base material 100 or similar interface. This reduces an increase in equivalent motional resistance and provides a highly-reliable oscillator 600.

### Method for Fabricating Oscillator

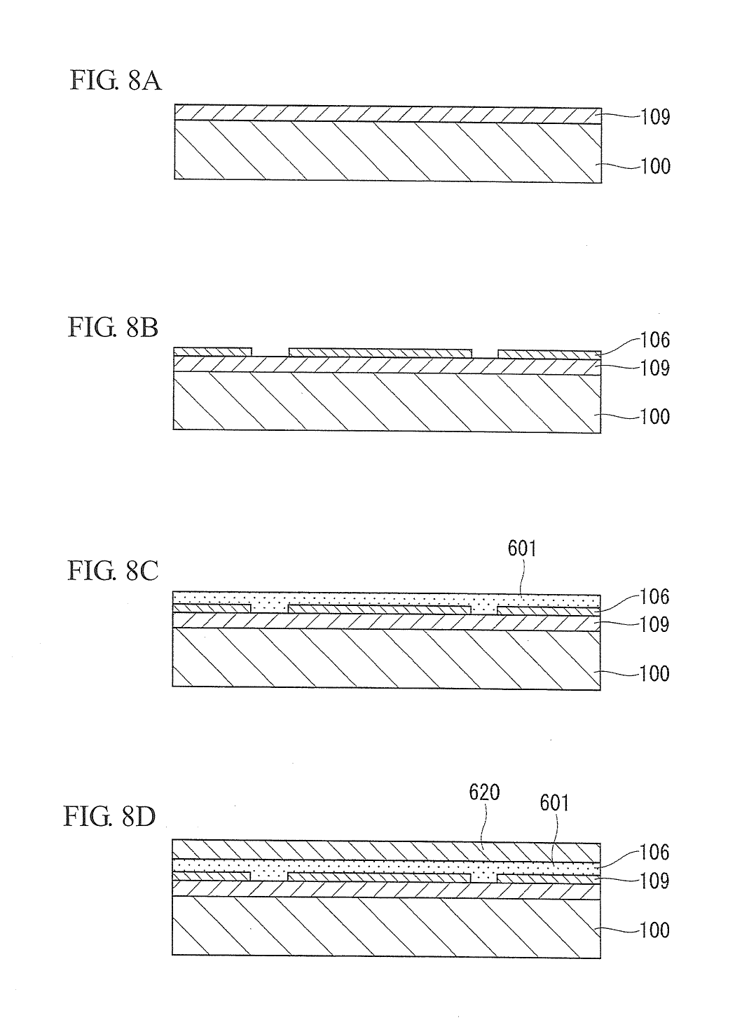

Next, a method for fabricating the oscillator 600 will be described. Firstly, as illustrated in FIG. 8A, a two-layer non-doped silicon oxidized film (NSG film) is formed on the surface of the base material 100 by a CVD method so as to form the first insulating layer 109. Subsequently, as illustrated in FIG. 8B, a first conducting layer 106 formed of, for example, a polysilicon film doped with phosphorus or boron is formed on the surface of the first insulating layer 109 by CVD, sputtering, or similar method so as to give electric conductivity. A pattern is formed by a photolithography technique such as resist coating, exposure, developing so as to form an wiring layer in a predetermined shape. Hereinafter, the first conducting layer 106 is referred to as an wiring layer 106.

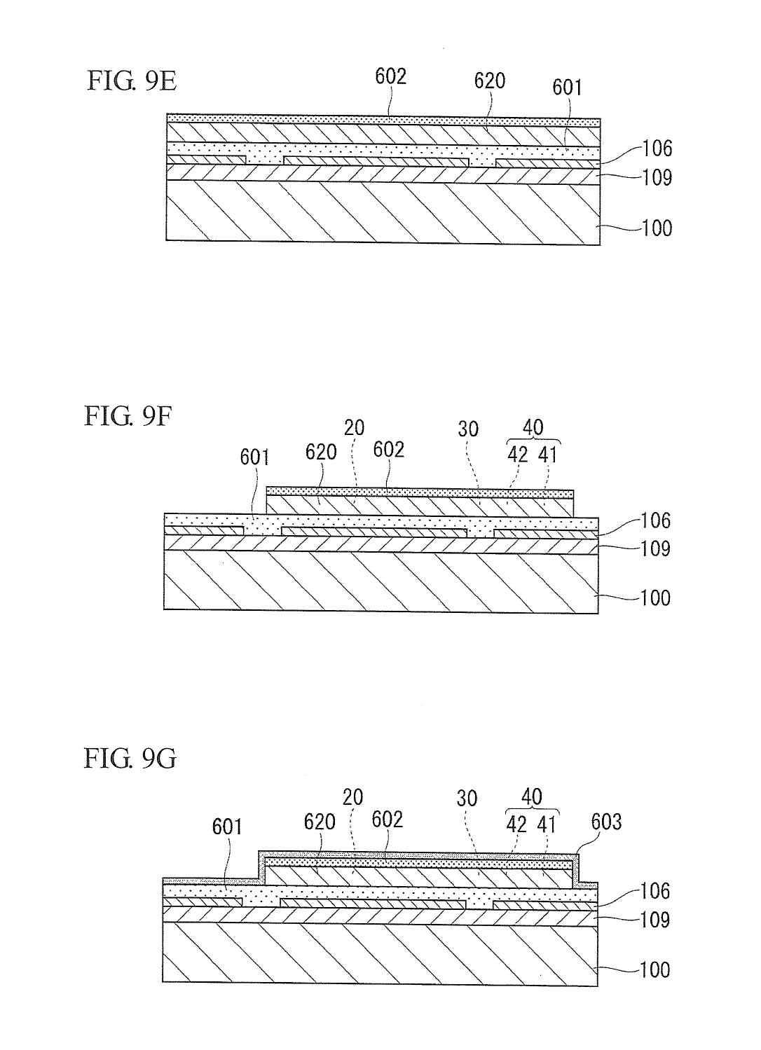

Subsequently, as illustrated in FIG. 8C, a first sacrificial layer 601 made of PSG or similar material is formed by CVD, sputtering, or similar method from upward of the wiring layer 106. Subsequently, as illustrated in FIG. 8D, a second conducting layer 620 made of a polysilicon film or similar film is formed on the surface of the first sacrificial layer 601 by CVD or similar method. Subsequently, as illustrated in FIG. 9E, a second sacrificial layer 602 made of a non-doped silicate glass (NSG) is formed on the surface of the second conducting layer 620 by CVD, sputtering or similar method. Subsequently, as illustrated in FIG. 9F, patterns of the second conducting layer 620 and the second sacrificial layer 602 are formed by a photolithography technique so as to form the disk portion 20, the supporting joists 30 and the securing portions 40 (the first rod-shaped portion 41 and the second rod-shaped portion 42) (a resonator forming step).

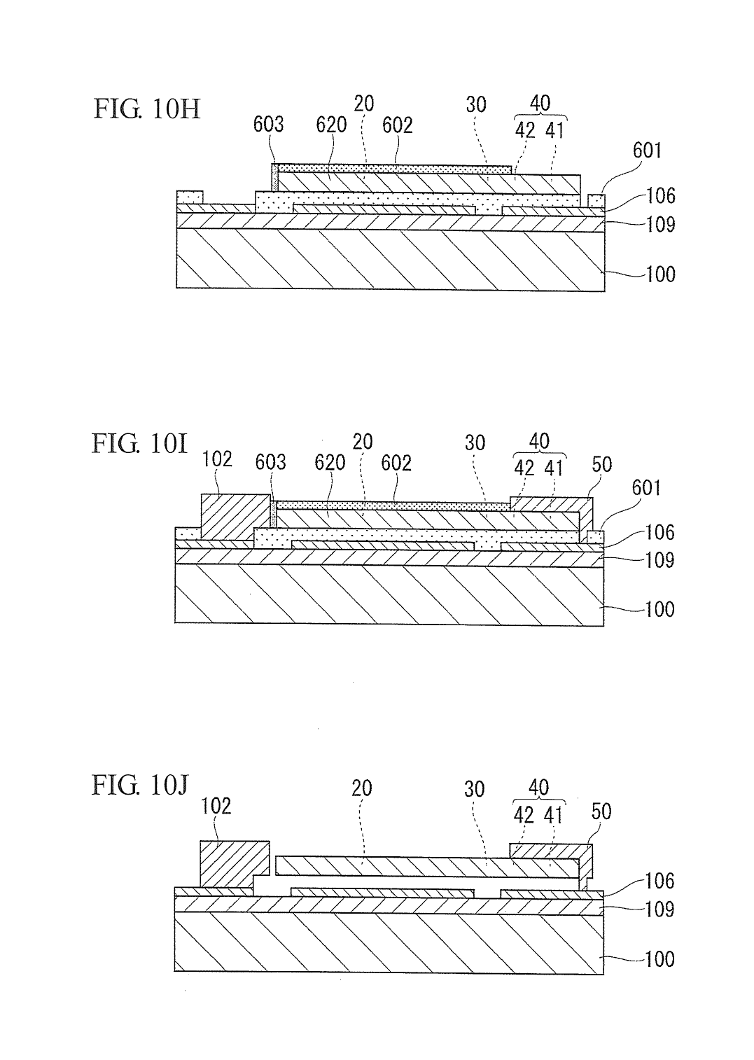

Subsequently, as illustrated in FIG. 9G a third sacrificial layer 603 made of NSG is formed on the second sacrificial layer 602 by CVD, sputtering, or similar method. Subsequently, as illustrated in FIG. 10H, a photolithography technique is used to form respective patterns of the third sacrificial layer 603, the second sacrificial layer 602, and the first sacrificial layer 601, so as to expose a part of the wiring layer 106. Subsequently, as illustrated in FIG. 10I, for example, a polysilicon film is formed by CVD from the above of the second sacrificial layer 602. A photolithography technique is used to form respective patterns of the bonding portion 50, the input electrode 102, and the output electrode 103 (a bonding step and an electrode forming step). In the drawing, the bonding portion 50 and the input electrode 102 are illustrated.

In this fabrication method, formation of the bonding portion 50 (the bonding step) and formation of the input electrodes 102 and the output electrodes 103 (the electrode forming step) are simultaneously performed. This, however, should not be construed in a limiting sense. For example, the bonding portion 50 may be formed in advance. Subsequently, the input electrode 102 and the output electrode 103 may be formed.

Subsequently, as illustrated in FIG. 10J, the first sacrificial layer 601, the second sacrificial layer 602, and the third sacrificial layer 603 are removed in an etching process or similar process using an etchant such as hydrogen fluoride (as a removal step), so as to form the oscillator 600.

Thus, in the bonding step, the base material 100 is bonded to not an anchor hole, but the bonding portion 50 that covers the rod-shaped securing portion 40. Therefore, foreign matter is unlikely to remain in the exposure process, the cleaning process, or similar process. This reduces invasion of foreign matter into the interface between the bonding portion 50 and the base material 100 and into the interface between the bonding portion 50 and the securing portion 40, so as to strongly bond both the portions and prevent an increase in equivalent motional resistance. This reduces occurrence of defects, thus efficiently fabricating the oscillator. Additionally, simultaneously performing the bonding step and the electrode forming step simplifies the fabrication process and reduces fabrication cost.

### Other Embodiments of Securing Portion and Similar Embodiment

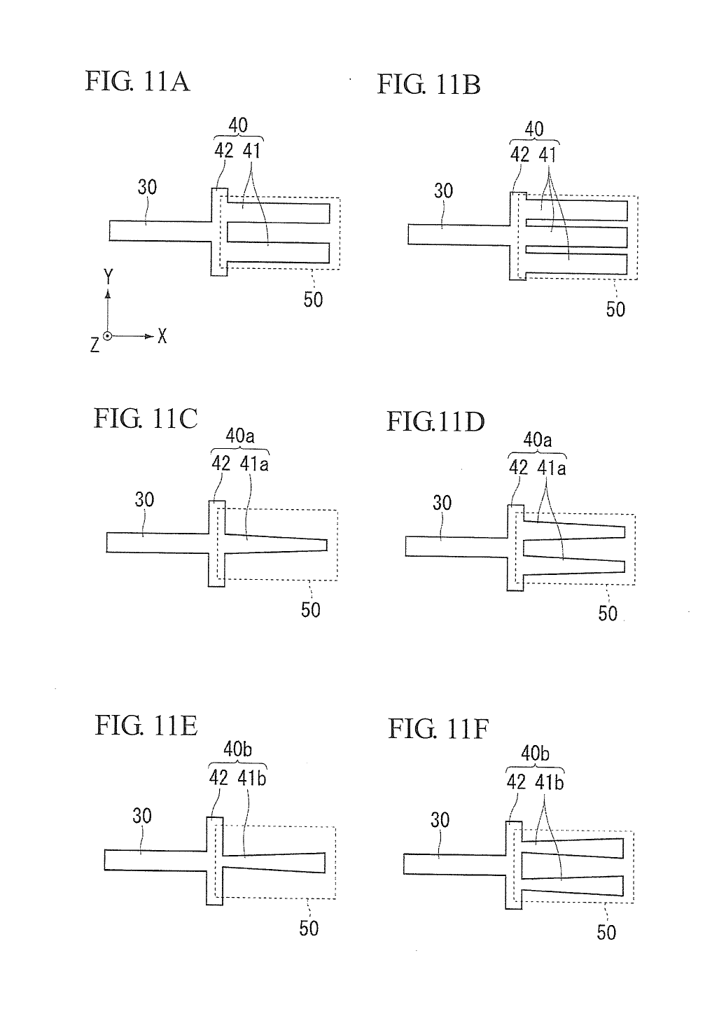

While in the description above the first to sixth embodiments regarding the resonator have been described, the securing portion of each resonator can be modified in various embodiments described below. In the following description, like reference numerals designate corresponding or identical elements throughout the first embodiment, and therefore such elements will not be further elaborated or will be simplified here. FIG. 11A to FIG. 11F are plan views of securing portions 40, 40a, and 40b viewed from the Z direction. While the coordinate system is illustrated only in FIG. 11A, the coordinate system is similar in FIG. 11B to FIG. 11F.

The securing portion 40 illustrated in FIG. 11A includes the two first rod-shaped portions 41 formed along the X direction in parallel. The securing portion 40 illustrated in FIG. 11B includes the three first rod-shaped portions 41 formed along the X direction in parallel at regular intervals.

In FIG. 11A and FIG. 11B, the first rod-shaped portions 41 each have the same shape and the same direction (the X direction). This, however, should not be construed in a limiting sense. For example, the respective first rod-shaped portions 41 may have any length along the X direction, and may have any direction. Furthermore, the number of the first rod-shaped portion 41 is not limited to two or three, and may be equal to or more than four. In the case where three or more of the first rod-shaped portions 41 are formed, the first rod-shaped portions 41 are not limited to be arranged at regular intervals. Thus, forming two or more of the first rod-shaped portions 41 has an advantage to enlarge the bonded area with the bonding portion 50 and enhances the bonding strength.

The securing portion 40a illustrated in FIG. 11C includes a first rod-shaped portion 41a formed in a shape gradually thinned toward the distal end (the +X direction) (where a cross-sectional area decreases along the longitudinal direction). The securing portion 40a illustrated in FIG. 11D includes two of this first rod-shaped portions 41a formed in parallel. The first rod-shaped portion 41a has a constant thinning rate (a reducing rate). This, however, should not be construed in a limiting sense. The thinning rate may be varied.

In FIG. 11C and FIG. 11D, the first rod-shaped portions 41a has the same shape and the same direction. This, however, should not be construed in a limiting sense. For example, the respective first rod-shaped portions 41a can be arbitrarily designed such that the respective thinning rates are varied, the respective directions are varied, or the respective lengths along the X direction are varied. The number of the first rod-shaped portions 41a is not limited to one or two, and may be equal to or more than three. The second rod-shaped portion 42 may be formed such that the cross-sectional area in the X direction changes along the longitudinal direction (the Y direction).

The securing portion 40b illustrated in FIG. 11E includes a first rod-shaped portion 41b formed in a shape gradually thickened toward the distal end (the +X direction) (where a cross-sectional area increases along the longitudinal direction). The securing portion 40b illustrated in FIG. 11F includes two of this first rod-shaped portions 41b formed in parallel. The first rod-shaped portion 41b has a constant thickening rate (an increasing rate). This, however, should not be construed in a limiting sense. The thickening rate may be varied.

In FIG. 11E and FIG. 11F, the first rod-shaped portions 41b each have the same shape and the same direction. This, however, should not be construed in a limiting sense. For example, the respective first rod-shaped portions 41b can be arbitrarily designed such that the respective thickening rates are varied, the respective directions are varied, or the respective lengths along the X direction are varied. The number of the first rod-shaped portions 41b is not limited to one or two, and may be equal to or more than three. Thus, the gradually thickened first rod-shaped portion 41b has an advantage to prevent pulling out from the bonding portion 50. Similarly to the description in FIG. 11C and FIG. 11D, the second rod-shaped portion 42 may be formed such that the cross-sectional area in the X direction changes along the longitudinal direction (the Y direction).

The embodiment has been described above. However, this disclosure is not limited to the above-described embodiment, and various changes of the embodiment may be made without departing from the spirit and scope of the disclosure. The matters described in the first to sixth embodiments may be combined as necessary. For example, a part of securing portions formed in the disk portion 20 may be the securing portion 40 of the resonator 10 according to the first embodiment while the other securing portions employ the securing portions 340 of the resonator 310 according to the fourth embodiment.

While in the above-described embodiment the resonator includes the disk-shaped disk portion 20 as a resonator main body, the resonator is not limited to this. For example, the resonator main body may be ring-shaped. In the case where the resonator main body is ring-shaped, the resonator main body can employ any ring shape such as a multangular shape, an elliptical shape, and an oval-like shape other than an annular shape. Additionally, in the case where the resonator main body is ring-shaped, the supporting joist may employ any of the configuration extending outwardly from the outer periphery of the ring and a configuration extending inwardly from an inner periphery of the ring.

Additionally, the first direction may be a direction along which the supporting joist extends. Additionally, the second rod-shaped portion may be formed at each of a resonator main body side and a distal end side of the first rod-shaped portion. Additionally, the second rod-shaped portion may be formed longer than the first rod-shaped portion. Additionally, a plurality of at least one of the first rod-shaped portions and the second rod-shaped portions may be formed. Additionally, at least one of the first rod-shaped portion and the second rod-shaped portion may be formed to have a cross-sectional area that changes along a longitudinal direction.

This disclosure provides an oscillator. The oscillator includes the above-described resonator and a bonding portion. The bonding portion bonds a front surface and a side surface of the first rod-shaped portion to a base material and bonds a front surface and a side surface of the second rod-shaped portion to the base material, in a state where the resonator main body and the supporting joist are separated from the base material.

This disclosure provides a method for fabricating an oscillator. The method includes a resonator forming step, a bonding step, and a removal step. The resonator forming step forms the above-described resonator on a base material across a sacrificial layer. The bonding step bonds a front surface and a side surface of the first rod-shaped portion to the base material, and bonds a front surface and a side surface of the second rod-shaped portion to the base material, with a bonding portion. The removal step removes the sacrificial layer. Additionally, the method for fabricating the oscillator may further include an electrode forming step that forms an electrode facing the resonator main body on the base material. The electrode may be formed of a same material as a material of the bonding portion. The electrode forming step and the bonding step may be simultaneously performed.

According to the embodiment, the securing portion is secured to the base material using the first rod-shaped portion and the second rod-shaped portion of the securing portion. When the securing portion is secured to the base material, there is no process via a through-hole (an anchor hole). Thus, foreign matter is unlikely to remain in an exposure process, a cleaning process, or similar process. This increases the bonding strength to the base material, thus reliably and stably securing the resonator main body. Furthermore, foreign matter does not intervene at the bonding surface. This reduces an increase in equivalent motional resistance and provides a highly-reliable resonator and oscillator.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A resonator comprising:
a ring-shaped or disk-shaped resonator main body;
a supporting joist that extends from the resonator main body to support the resonator main body; and
a securing portion formed at a distal end of the supporting joist, the securing portion being secured to a base material, wherein
the securing portion includes:
a first rod-shaped portion formed in a first direction; and
a second rod-shaped portion formed in a second direction different from the first direction.

2. The resonator according to claim 1, wherein
the first direction is a direction along which the supporting joist extends.

3. The resonator according to claim 1, wherein
the second rod-shaped portion is formed at each of a resonator main body side and a distal end side of the first rod-shaped portion.

4. The resonator according to claim 2, wherein
the second rod-shaped portion is formed at each of a resonator main body side and a distal end side of the first rod-shaped portion.

5. The resonator according to claim 1, wherein
the second rod-shaped portion is formed longer than the first rod-shaped portion.

6. The resonator according to claim 2, wherein
the second rod-shaped portion is formed longer than the first rod-shaped portion.

7. The resonator according to claim 3, wherein
the second rod-shaped portion is formed longer than the first rod-shaped portion.

8. The resonator according to claim 1, wherein
at least one of the first rod-shaped portions and the second rod-shaped portions is formed in plurality.

9. The resonator according to claim 2, wherein
at least one of the first rod-shaped portions and the second rod-shaped portions is formed in plurality.

10. The resonator according to claim 3, wherein
at least one of the first rod-shaped portions and the second rod-shaped portions is formed in plurality.

11. The resonator according to claim 5, wherein
at least one of the first rod-shaped portions and the second rod-shaped portions is formed in plurality.

12. The resonator according to claim 1, wherein
at least one of the first rod-shaped portion and the second rod-shaped portion is formed to have a cross-sectional area that changes along a longitudinal direction.

13. The resonator according to claim 2, wherein
at least one of the first rod-shaped portion and the second rod-shaped portion is formed to have a cross-sectional area that changes along a longitudinal direction.

14. The resonator according to claim 3, wherein
at least one of the first rod-shaped portion and the second rod-shaped portion is formed to have a cross-sectional area that changes along a longitudinal direction.

15. The resonator according to claim 5, wherein
at least one of the first rod-shaped portion and the second rod-shaped portion is formed to have a cross-sectional area that changes along a longitudinal direction.

16. The resonator according to claim 8, wherein
at least one of the first rod-shaped portion and the second rod-shaped portion is formed to have a cross-sectional area that changes along a longitudinal direction.

17. An oscillator, comprising:
the resonator according to claim 1;
a bonding portion that bonds a front surface and a side surface of the first rod-shaped portion to the base material and bonds a front surface and a side surface of the second rod-shaped portion to the base material, in a state where the resonator main body and the supporting joist are separated from the base material.

18. A method for fabricating an oscillator, comprising:
a resonator forming step of forming the resonator according to claim 1 on a base material across a sacrificial layer;
a bonding step of: bonding a front surface and a side surface of the first rod-shaped portion to the base material; and bonding a front surface and a side surface of the second rod-shaped portion to the base material, with a bonding portion; and
a removal step of removing the sacrificial layer.

19. The method for fabricating the oscillator according to claim 18, further comprising
an electrode forming step of forming an electrode facing the resonator main body on the base material, wherein
the electrode is formed of a same material as a material of the bonding portion, and
the electrode forming step and the bonding step are simultaneously performed.
